(19) United States
(12) Patent Application Publication
(10) Pub. No.: US 2016/0095197 A1
(43) Pub. Date: Mar. 31, 2016

(54) CIRCUIT BOARD MODULE AND CIRCUIT BOARD STRUCTURE

(71) Applicant: BOARDTEK ELECTRONICS CORPORATION, TAOYUAN COUNTY (TW)

(72) Inventor: CHIEN-CHENG LEE, TAOYUAN COUNTY (TW)

(21) Appl. No.: 14/566,687

(22) Filed: Dec. 10, 2014

(30) Foreign Application Priority Data
Sep. 29, 2014 (TW) 103133733

(51) Int. Cl. H05K 1/02; H05K 7/20

(52) U.S. Cl. CPC H05K 1/0203; H05K 7/20336; H05K 2201/09036

(57) ABSTRACT

A circuit board module includes a circuit board structure, a heat generating element, and a cooling element. The circuit board structure has a plate component and a heat conductive component. The heat conductive component has a heat pipe and a resin excluding fiber glass. The heat pipe is disposed in the plate component and not protruding from the plate component. The resin fills a gap between the heat pipe and the plate component, and the resin substantially connects the heat pipe and the plate component without any gap. The heat generating element contacts the heat conductive component, and a portion of the heat conductive component adjacent to the heat generating element is defined as a heat absorbing portion. The cooling element contacts the heat conductive component, and a portion of the heat conductive component adjacent to the cooling element is defined as a heat dissipating portion.

### BACKGROUND OF THE INVENTION

1. Field of the Invention

The instant disclosure relates to a circuit board; in particular, to a circuit board module with thermally conductive phase change type and a circuit board structure.

2. Description of Related Art

Conventional electronic products, such as cell phones and note books, are provided with higher and higher stacking density of packaging module in the trend of miniaturization. Moreover, the functions and the power consumption of the electronic products are gradually increased, so that the electronic products in operation will generate a lot of heat, thereby increasing the temperature of the electronic products. Accordingly, in order to reduce decreased reliability of the electronic products resulted from the high temperature, copper pillars are usually provided to a circuit board to be a heat dissipating path of the electronic components.

However, the heat-dissipating efficiency of the circuit board having the copper pillars has become insufficient. Thus, how to increase the heat-dissipating efficiency of the circuit board is one of the main topics. To achieve the abovementioned improvement, the inventors strive via industrial experience and academic research to present the instant disclosure, which can provide additional improvement as mentioned above.

### SUMMARY OF THE INVENTION

One embodiment of the instant disclosure provides a circuit board module and a circuit board structure for increasing heat-dissipating efficiency.

The circuit board module of the instant disclosure comprises: a circuit board structure comprising: a plate component having two surfaces and at least one signal transmission line, wherein the plate component has an accommodating slot; and a heat conductive component comprising: an enclosed heat pipe having a working fluid arranged therein, wherein the working fluid includes a working liquid and a working gas, the heat pipe is disposed in the accommodating slot and arranged without protruding from the two surfaces of the plate component, a gap exists between the heat pipe and the accommodating slot; and a resin configured without any glass fiber, wherein the resin is filled in the gap between the heat pipe and the accommodating slot, the heat pipe is electrically isolated from the signal transmission line; a heat generating element contacts the heat conductive component of the circuit board structure, wherein a portion of the heat pipe arranged adjacent to the heat generating element is defined as a heat absorbing portion; and a cooling element contacts the heat conductive component of the circuit board structure, wherein a portion of the heat pipe arranged adjacent to the cooling element is defined as a heat dissipating portion; wherein the working fluid arranged in the heat absorbing portion trends to change from the working liquid to the working gas by absorbing heat generated from the heat generating element, thereby generating a high pressure in the heat absorbing portion for driving the working gas to flow to the heat dissipating portion; when the working gas is arranged in the heat dissipating portion, the working gas is cooled to become the working liquid by the cooling element and flows to the heat generating element.

The circuit board structure of the instant disclosure comprises: a plate component having two surfaces and at least one signal transmission line, wherein the plate component has an accommodating slot; and a heat conductive component comprising: an enclosed heat pipe having a working fluid arranged therein, wherein the working fluid includes a working liquid and a working gas, the heat pipe is disposed in the accommodating slot and arranged without protruding from the two surfaces of the plate component, a gap exists between the heat pipe and the accommodating slot, the heat pipe has a heat absorbing portion and a heat dissipating portion; and a resin configured without any glass fiber, wherein the resin is filled in the gap between the heat pipe and the accommodating slot, the resin is substantially and seamlessly connected to the heat pipe and the accommodating slot, the heat pipe is electrically isolated from the signal transmission line; wherein the working fluid arranged in the heat absorbing portion trends to change from the working liquid to the working gas by absorbing heat, thereby generating a high pressure in the heat absorbing portion for driving the working gas to flow to the heat dissipating portion; when the working gas is arranged in the heat dissipating portion, the working gas is cooled to become the working liquid by cooling and flows to the heat generating element.

In summary, the circuit board module and the circuit board structure of the instant disclosure are provided to rapidly transfer heat generated from the heat generating element to the cooling element by the heat pipe arranged in the circuit board structure, thereby increasing the heat-dissipating efficiency of the circuit board structure.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is a perspective view showing a circuit board module according to the instant disclosure;

FIG. 2 is a cross-sectional view of FIG. 1 along line A-A;

FIG. 3 is a cross-sectional view of FIG. 1 along line B-B;

FIG. 4 is a perspective view showing the step S101 of the manufacturing method of the circuit board structure;

FIG. 5 is a perspective view showing the step S103 of the manufacturing method of the circuit board structure;

FIG. 6 is a perspective view showing the step S105 of the manufacturing method of the circuit board structure;

FIG. 7 is a perspective view showing the step S107 of the manufacturing method of the circuit board structure;

FIG. 8 is a perspective view showing the step S109 of the manufacturing method of the circuit board structure;

FIG. 9 is perspective view showing the circuit board structure according to another embodiment;

FIG. 10 is a perspective view showing the circuit board module corresponding to FIG. 7;

FIG. 11 is a perspective view showing the circuit board module corresponding to FIG. 7 from another viewing angle;

FIG. 12 is a cross-sectional view of the FIG. 10 along line C-C;

FIG. 13 is perspective view showing the circuit board module according to the other embodiment; and

FIG. 14 is a perspective view showing the circuit board module corresponding to FIG. 8.

### DETAILED DESCRIPTION OF THE PREFERRED EMBODIMENTS

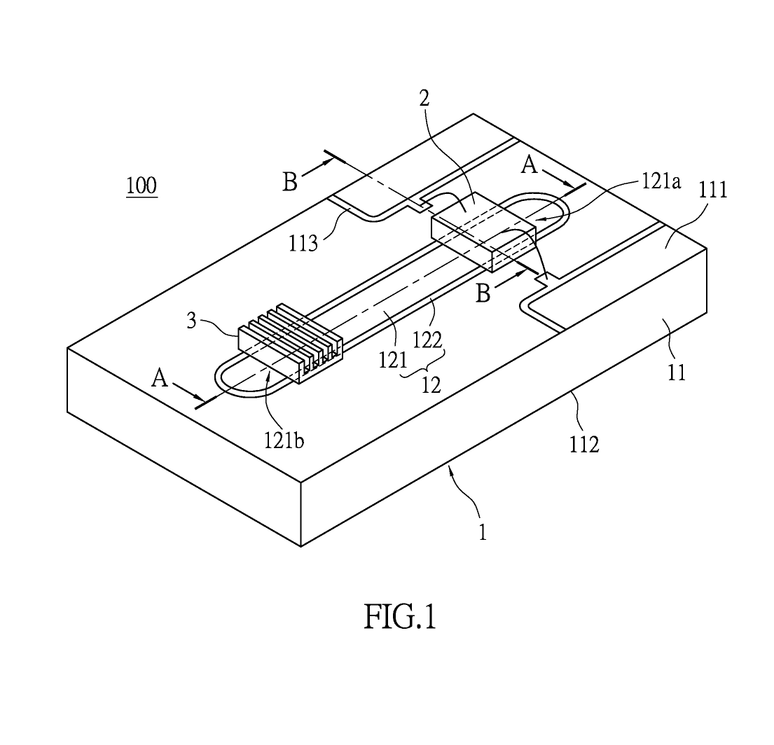

Please refer to FIGS. 1 through 3, which show an embodiment of the instant disclosure. References are hereunder made to the detailed descriptions and appended drawings in connection with the instant disclosure. However, the appended drawings are merely shown for exemplary purposes, rather than being used to restrict the scope of the instant disclosure.

The instant embodiment provides a circuit board module 100 with thermally conductive phase change type. The circuit board module 100 includes a circuit board structure 1, a heat generating element 2, and a cooling element 3. The heat generating element 2, and the cooling element 3 are mounted on the circuit board structure 1 for transferring heat generated from the heat generating element 2 to the cooling element 3 by the circuit board structure 1. The heat generating element 2 can be chip or resistor, the cooling element 3 can be heat-dissipating fins or cooling chip, but the heat generating element 2 and the cooling element 3 are not limited thereto.

The following description discloses the specific construction of the circuit board structure 1, and then discloses the relationship of the circuit board structure 1, the heat generating element 2, and the cooling element 3.

The circuit board structure 1 has a plate component 11 and a heat conductive component 12 embedded in the plate component 11. The plate component 11 in the instant embodiment is an inflexible board, which cannot be bent. Specifically, the plate component 11 is formed by a preimpregnated material, and the preimpregnated material can be glass fiber prepreg, carbon fiber prepreg, or epoxy resin. Moreover, the plate component 11 in the instant embodiment is a laminated plate for example, but is not limited thereto. In order to clearly disclose the instant embodiment, the following description takes the laminated plate to be one piece for explaining the plate component 11.

The plate component 11 has two surfaces 111, 112 respectively arranged at two opposite sides thereof (e.g., the top surface and the bottom surface of the plate component 11 as shown in FIG. 1, hereafter referred to a first surface 111 and a second surface 112). The plate component 11 has at least one signal transmission line 113 for transmitting signal.

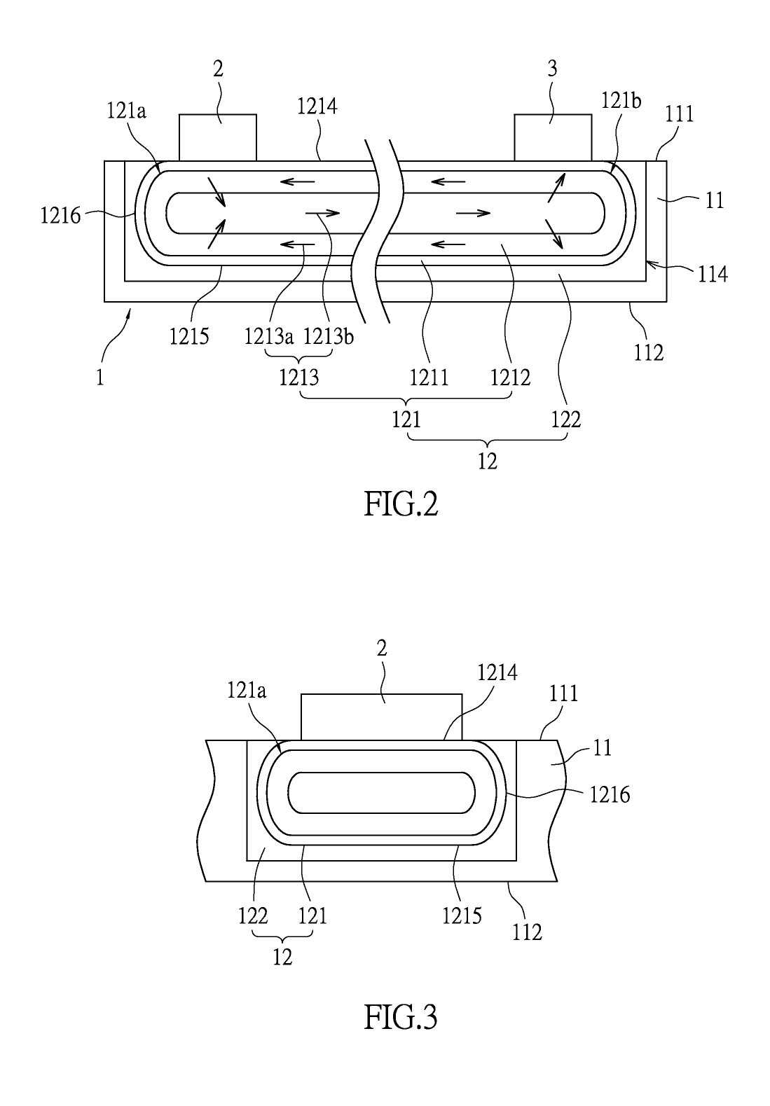

Moreover, the plate component 11 has an accommodating slot 114 recessed from one of the first surface 111 and the second surface 112, and the accommodating slot 114 as shown in FIG. 2 is recessed from the first surface 111 for example. The accommodating slot 114 is elongated, and the longitudinal direction of the accommodating slot 114 (e.g., the horizontal direction as shown in FIG. 2) is approximately parallel to the first surface 111 and the second surface 112. Besides, the other features of the plate component 11, such as via hole or circuit layout, are not important features of the instant disclosure, so the instant embodiment does not disclose the unimportant features.

The heat conductive component 12 has an enclosed heat pipe 121 and a resin 122 provided without any glass fiber. The heat pipe 121 is approximately flat, the contour of the heat pipe 121 approximately corresponds to the accommodating slot 114 of the plate component 11, and the size of the heat pipe 121 is slightly smaller than the accommodating slot 114. The heat pipe 121 has a tube 1211 (e.g., copper tube), a capillary configuration 1212 formed on the inner wall of the tube 1211, and a working fluid 1213 (e.g., water) arranged in the tube 1211. The heat pipe 121 in the instant embodiment is straight, but the shape of the heat pipe 121 can be changed according to the designer's request. For example, the heat pipe 121 can be bent to form an L shape (not shown).

The heat pipe 121 is arranged in the accommodating slot 114 of the plate component 11 and is not protruding from the first and second surfaces 111, 112 of the plate component 11. A gap exists between the heat pipe 121 and the accommodating slot 114. The heat pipe 121 is electrically isolated from the signal transmission line 113. The resin 122 is filled in the gap arranged between the heat pipe 121 and the accommodating slot 114, and the resin 122 is substantially and seamlessly connected to the heat pipe 121 and the accommodating slot 114, such that the heat pipe 121 is firmly embedded in the plate component 11.

Specifically, the heat pipe 121 has a heat absorbing portion 121a and a heat dissipating portion 121b. The heat absorbing portion 121a in the instant embodiment refers to a portion of the heat pipe 121 arranged adjacent to the heat generating element 2 (e.g., the left portion of the heat pipe 121 as shown in FIG. 2). The heat dissipating portion 121b in the instant embodiment refers to a portion of the heat pipe 121 arranged adjacent to the cooling element 3 (e.g., the right portion of the heat pipe 121 as shown in FIG. 2).

The outer surface of the heat pipe 121 includes two opposite main surfaces 1214, 1215 (hereafter referred to as a first main surface 1214 and a second main surface 1215) and a surrounding side surface 1216 connecting the edges of the main surfaces 1214, 1215. The first main surface 1214 of the heat pipe 12 is exposed from the first surface 111 of the plate component 11, and the second main surface 1215 and the side surface 1216 are covered by the resin 122 and embedded in the plate component 11.

Moreover, the first main surface 1214 of the heat pipe 121 and an outer surface of the resin 122, which are exposed from the first surface 111 of the plate component 11, are approximately coplanar with the first surface 111 of the plate component 11. That is to say, part of the first main surface 1214 corresponding to the heat absorbing portion 121a and the adjacent outer surface of the resin 122 are approximately coplanar with the first surface 111 of the plate component 11. Part of the first main surface 1214 corresponding to the heat dissipating portion 121b and the adjacent outer surface of the resin 122 are approximately coplanar with the first surface 111 of the plate component 11.

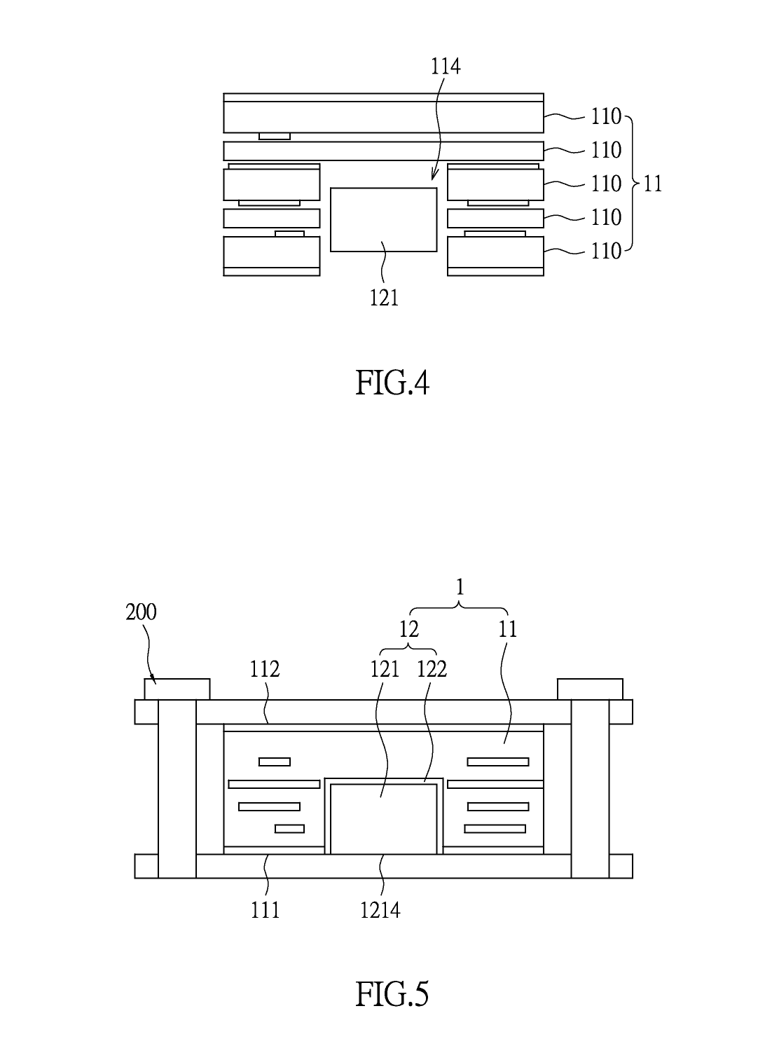

The above description discloses the features of the circuit board structure 1, and the following description briefly discloses the manufacturing method and some varieties of the circuit board structure 1 for further explaining the circuit board structure 1 provided by the instant embodiment. Please refer to FIGS. 4 through 6, which show the cross-sectional view of the circuit board structure 1 (e.g., the cross-sectional view of the circuit board structure 1 in FIG. 1 along line B-B) to introduce the steps of the manufacturing method of the circuit board structure 1.

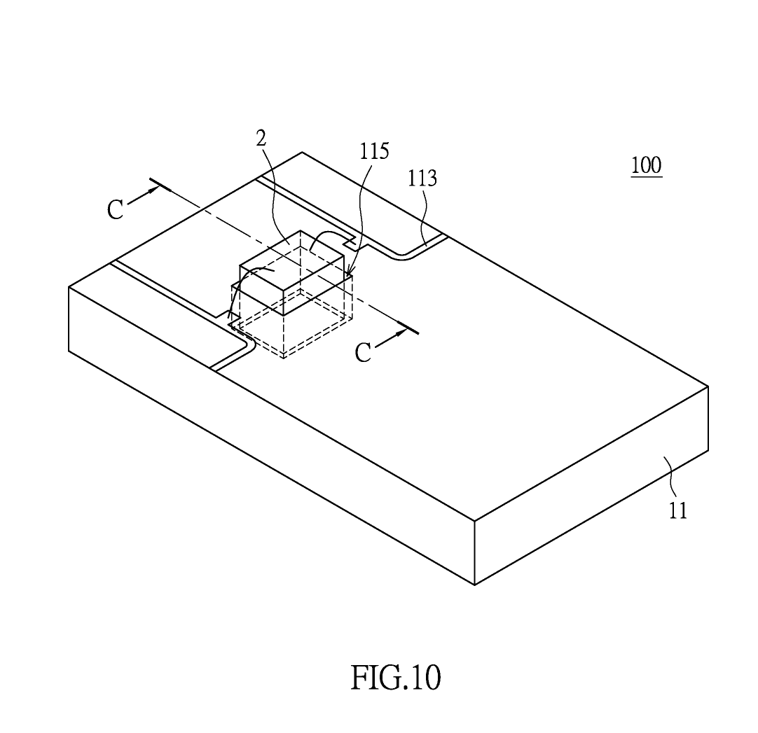

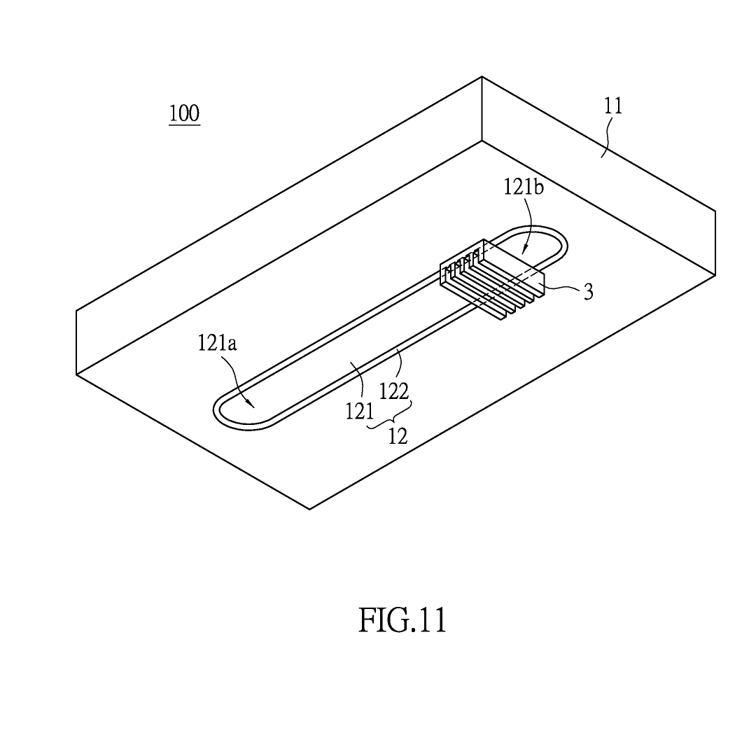

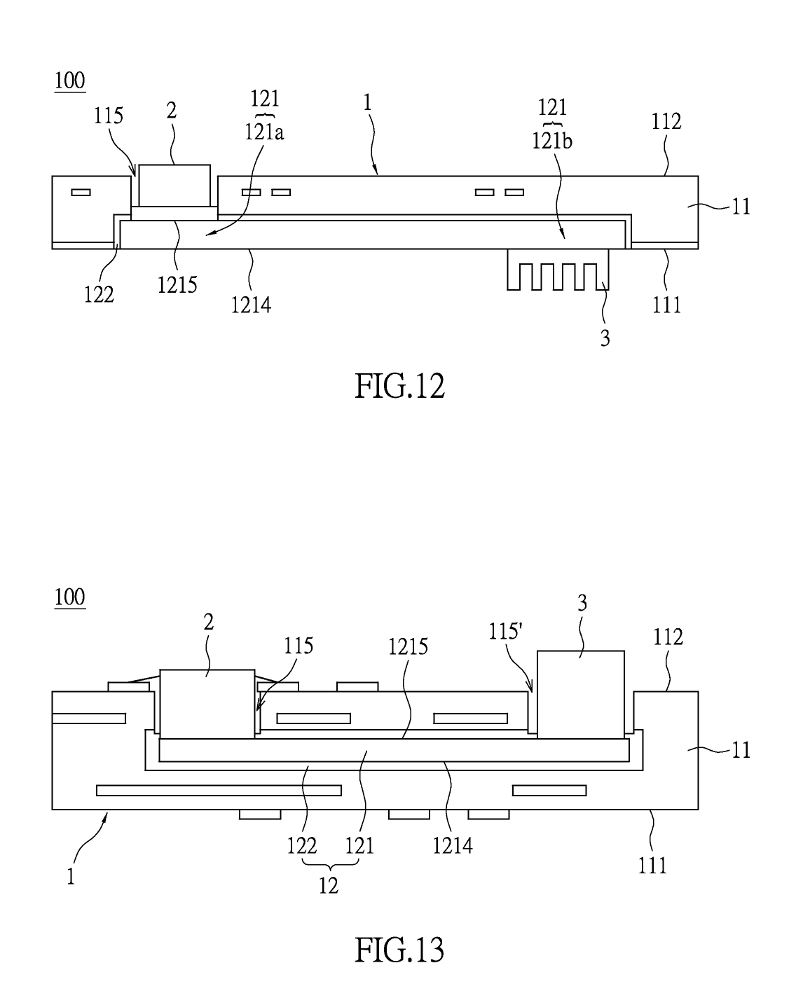

Moreover, the heat pipe 121 of FIGS. 4 through 14 is presented as one piece and not shown with the detailed construction thereof, that is to say, the tube 1211, the capillary configuration 1212, and the working fluid 1213 are not shown and labeled, thereby saving the Figures from complication.

The step S101: as shown in FIG. 4, provide a plurality of plates 110, in which some of the plates 110 each has a hole. Stack the plates 110 to form the plate component 11, in which the holes of the plates 110 are in fluid communication to form the accommodating slot 114. That is to say, the walls defining the holes are configured to form the side wall of the accommodating slot 114. And then, put the heat pipe 121 into the accommodating slot 114 of the plate component 11.

The step S103: as shown in FIG. 5, inject the resin 122 into the gap of the accommodating slot 114, which is arranged between the plate component 11 and the heat pipe 121, until the gap of the accommodating slot 114 is fully filled with the resin 122. And then, cool the resin 122 to dissipate bubble generated in the resin 122. Compress the first and second surfaces 111, 112 of the plate component 11 and the first main surface 1214 of the heat pipe 121 in high temperature by a mold for extruding part of the resin 122, thereby preventing the circuit board structure 1 from warping during the compressing process.

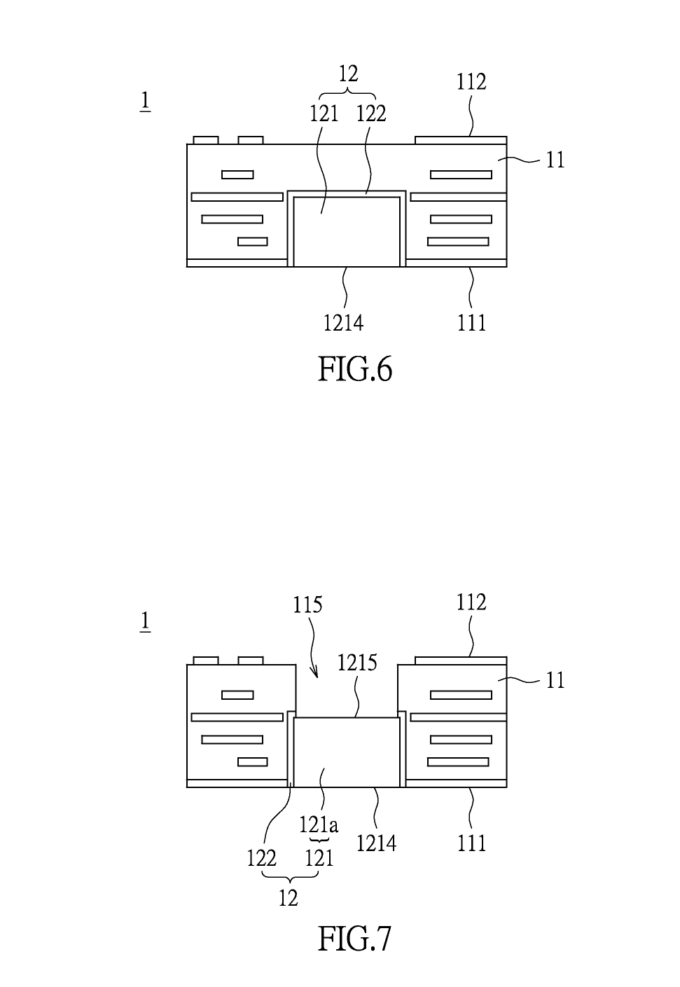

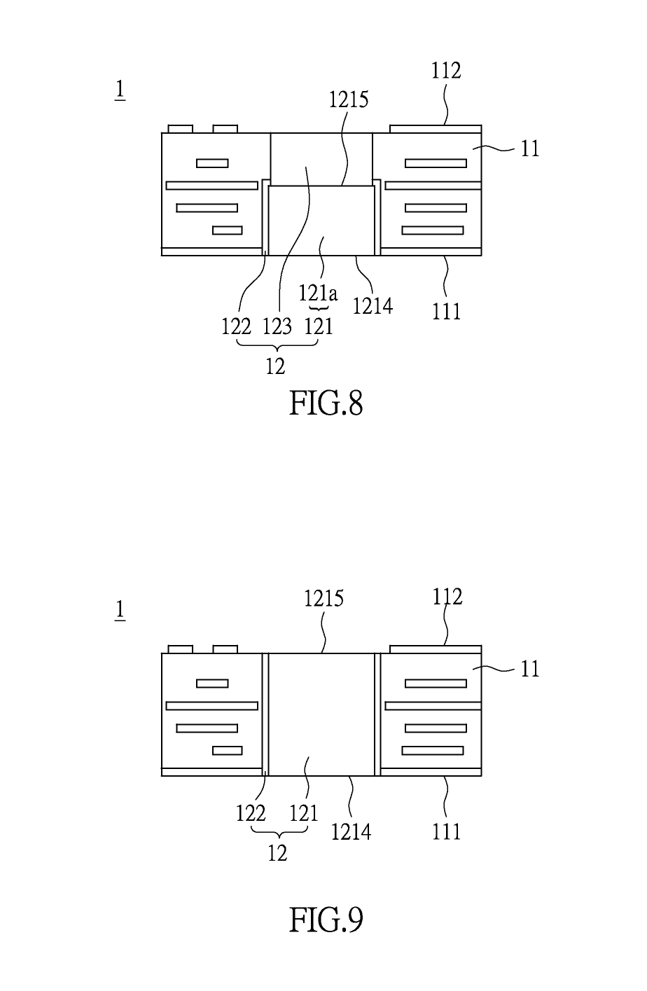

The step S105: as shown in FIG. 6, form a predetermined circuit construction on the circuit board structure 1, such as forming the signal transmission line 113 on the first surface 111 or the second surface 112, or forming a via hole on the circuit board structure 1. Thus, the circuit board structure 1 as shown in FIG. 6 is as shown in the cross-sectional view of the circuit board structure 1 of FIG. 1 along line B-B. In other words, the circuit board structure 1 produced after the step S105 can be used to bond the heat generating element 2 and the cooling element 3. However, the circuit board structure 1 can be further processed to form another construction, such as the constructions in FIGS. 7 and 8, but is not limited thereto.

The step S107: as shown in FIG. 7, after the step S105, form a trough 115 from a portion of the second surface 112, which is corresponding to the heat absorbing portion 121a, to the second main surface 1215 of the heat absorbing portion 121a. That is to say, the trough 115 is formed between the second surface 112 of the plate component 11 and the second main surface 1215 of the heat pipe 121 corresponding to the heat absorbing portion 121a. Moreover, the size of the trough 115 must be large enough to receive the heat generating element 2.

The processing manner of the trough 115 can be the chemical etching or non-chemical etching (e.g., laser drilling, plasma etching, or milling), but is not limited thereto. Moreover, the circuit board structure 1 produced after the step S107 can be used to bond the heat generating element 2 and the cooling element 3.

The step S109: as shown in FIG. 8 after the step S107, form a conductive body 123 in the trough 115 of the circuit board structure 1. The conductive body 123 in the instant embodiment is formed by coating metal ions (e.g., copper ions) in the trough 115, thereby forming a solid pillar construction. That is to say, the heat conductive component 12 can further have the conductive body 123. Moreover, the circuit board structure 1 produced after the step S109 can be used to bond the heat generating element 2 and the cooling element 3.

Incidentally, the order of each step of the instant embodiment can be adjusted, in other words, the instant disclosure does not limit the order of the steps. For example, the trough 115 can be correspondingly formed on the heat dissipating portion 121b, or the circuit board structure 1 can be produced to form as the construction in FIG. 9 by adjusting the order of the above steps.

The above description approximately discloses the circuit board structure 1, and then the following description discloses the relationship of the circuit board structure 1, the heat generating element 2, and the cooling element 3. Moreover, the relationship of the circuit board structure 1, the heat generating element 2, and the cooling element 3 in the following description is disclosed according to the construction as shown in FIGS. 1, 7, and 8. The identical features in FIGS. 1, 7, and 8 are not stated again.

Please refer to FIGS. 1 through 3. The heat generating element 2 and the cooling element 3 each contact the heat conductive component 12 of the circuit board structure 1, and the heat generating element 2 is electrically connected to the signal transmission line 113 of the circuit board structure 1 by wiring. Specifically, the heat generating element 2 contacts a portion of the first main surface 1214 of the heat pipe 121 corresponding to the heat absorbing portion 121a and exposed from the first surface 111. The cooling element 3 contacts a portion of the first main surface 1214 of the heat pipe 121 corresponding to the heat dissipating portion 121b and exposed from the first surface 111. The heat generating element 2 is disposed apart from the cooling element 3. Moreover, the heat generating element 2 contacts the portion of the first main surface 1214 of the heat pipe 121 corresponding to the heat absorbing portion 121a and the adjacent first surface 111 of the plate component 11 arranged coplanar with the first main surface 1214. The cooling element 3 contacts the portion of the first main surface 1214 of the heat pipe 121 corresponding to the heat dissipating portion 121b and the adjacent first surface 111 of the plate component 11 arranged coplanar with the first main surface 1214.

Incidentally, the contact manner of the heating generating element 2 and the cooling element 3 with respect to the heat pipe 121 can be direct contact with the heat pipe 121 or contact to the heat pipe 121 via a heat conductive gel (or the other adhesive component), but is not limited thereto.

Please refer to FIGS. 7, 10, and 12. The heat generating element 2 is at least partially embedded in the trough 115 of the circuit board structure 1 and is connected to a portion of the second main surface 1215 of the heat pipe 121 corresponding to the heat absorbing portion 121a, thereby reducing the height of the circuit board module 100, and the heat generating element 2 is electrically connected to the signal transmission line 113 of the circuit board structure 1 by wiring. The cooling element 3 contacts a portion of the first main surface 1214 of the heat pipe 121 corresponding to the heat dissipating portion 121b and exposed from the first surface 111.

Additionally, as shown in FIG. 13, the circuit board structure 1 can be produced with another trough 115′, which recesses from a portion of the second surface 112 corresponding to the heat dissipating portion 121b toward a portion of the second main surface 1215 corresponding to the heat dissipating portion 121b. The cooling element 3 is at least partially embedded in the trough 115′ and contacts a portion of the second main surface 1215 corresponding to the heat dissipating portion 121b. Moreover, the accommodating slot 114 can be formed between the first and second surfaces 111, 112, such that the heat pipe 121 can be entirely embedded in the plate component 11.

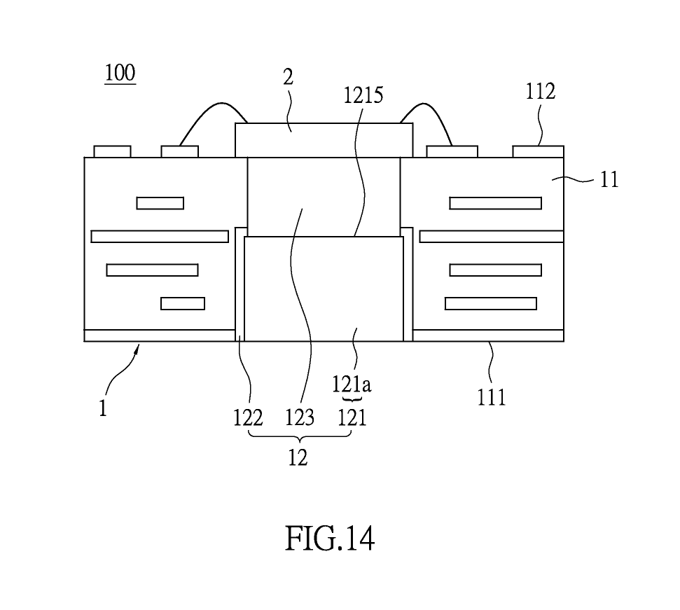

Referring to FIGS. 8 and 14, the heat generating element 2 contacts the conductive body 123 for transmitting the heat generated therefrom to the heat absorbing portion 121a of the heat pipe 121 via the conductive body 123. The heat generating element 2 is electrically connected to the signal transmission line 113 of the circuit board structure 1 by wiring.

As shown in FIG. 2, each kind of the circuit board structure 1 has the following features: the working fluid 1213 arranged in the heat absorbing portion 121a changes from the working liquid 1213a to the working gas 1213b by absorbing heat generated from the heat generating element 2, thereby generating a high pressure in the heat absorbing portion 121a for driving the working gas 1213b to flow to the heat dissipating portion 121b in a space surrounded by the capillary configuration 1212; when the working gas 1213b is arranged in the heat dissipating portion 121b, the working gas 1213b is cooled to become the working liquid 1213a by the cooling element 3 and flows to the heat generating element 121a along the capillary configuration 1212.

### [The Possible Effect of the Instant Disclosure]

In summary, the circuit board module and the circuit board structure of the instant disclosure are provided to rapidly transfer heat generated from the heat generating element to the cooling element by the heat pipe arranged in the circuit board structure, thereby increasing the heat-dissipating efficiency of the circuit board structure.

Moreover, the resin provided without any glass fiber is configured to connect the heat pipe and the accommodating slot of the plate component for embedding the heat pipe in the plate component more stably, thereby preventing the circuit board structure from warping during a pressing process.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A circuit board module, comprising:
a circuit board structure comprising:
a plate component having two surfaces and at least one signal transmission line, wherein the plate component has an accommodating slot; and
a heat conductive component comprising:
an enclosed heat pipe having a working fluid arranged therein, wherein the working fluid includes a working liquid and a working gas, the heat pipe is disposed in the accommodating slot and arranged without protruding from the two surfaces of the plate component, and a gap exists between the heat pipe and the accommodating slot; and
a resin configured without any glass fiber, wherein the resin fills the gap between the heat pipe and the accommodating slot, and the heat pipe is electrically isolated from the signal transmission line;
a heat generating element contacting the heat conductive component of the circuit board structure, wherein a portion of the heat pipe arranged adjacent to the heat generating element is defined as a heat absorbing portion; and
a cooling element contacting the heat conductive component of the circuit board structure, wherein a portion of the heat pipe arranged adjacent to the cooling element is defined as a heat dissipating portion;
wherein the working fluid arranged in the heat absorbing portion changes from the working liquid to the working gas by absorbing heat generated from the heat generating element, thereby generating a high pressure in the heat absorbing portion for driving the working gas to flow to the heat dissipating portion; when the working gas is arranged in the heat dissipating portion, the working gas is cooled by the cooling element to become the working liquid and flows to the heat generating element.

2. The circuit board module as claimed in claim 1, wherein the circuit board structure has a trough formed between a surface of the heat absorbing portion of the heat pipe and one of the surfaces of the plate component, and the heat generating element is at least partially arranged in the trough and contacts the surface of the heat absorbing portion.

3. The circuit board module as claimed in claim 1, wherein the circuit board structure has a trough formed between a surface of the heat absorbing portion of the heat pipe and one of the surfaces of the plate component, the heat conductive component has a pillar conductive body arranged in the trough, and the heat generating element contacts the conductive body.

4. The circuit board module as claimed in claim 1, wherein a surface of the heat absorbing portion of the heat pipe is approximately coplanar with one of the surfaces of the plate component, and the heat generating element contacts the surface of the heat absorbing portion and the adjacent surface of the plate component.

5. The circuit board module as claimed in claim 1, wherein the plate component is a laminated plate, the accommodating slot is formed between the two surfaces of the plate component, and the heat conductive component is embedded in the plate component.

6. The circuit board module as claimed in claim 1, wherein a surface of the heat dissipating portion of the heat pipe is approximately coplanar with one of the surfaces of the plate component, and the cooling element contacts the surface of the heat dissipating portion.

7. A circuit board structure, comprising:
a plate component having two surfaces and at least one signal transmission line, wherein the plate component has an accommodating slot; and
a heat conductive component comprising:
an enclosed heat pipe having a working fluid arranged therein, wherein the working fluid includes a working liquid and a working gas, the heat pipe is disposed in the accommodating slot and arranged without protruding from the two surfaces of the plate component, a gap exists between the heat pipe and the accommodating slot, and the heat pipe has a heat absorbing portion and a heat dissipating portion; and
a resin configured without any glass fiber, wherein the resin fills the gap between the heat pipe and the accommodating slot, the resin is substantially and seamlessly connected to the heat pipe and the accommodating slot, and the heat pipe is electrically isolated from the signal transmission line;
wherein the working fluid arranged in the heat absorbing portion changes from the working liquid to the working gas by absorbing heat, thereby generating a high pressure in the heat absorbing portion for driving the working gas to flow to the heat dissipating portion; when the working gas is arranged in the heat dissipating portion, the working gas is cooled to become the working liquid and flows to the heat generating element.

8. The circuit board structure as claimed in claim 7, wherein the circuit board structure has a trough formed between a surface of the heat absorbing portion of the heat pipe and one of the surfaces of the plate component, and an opposite surface of the heat absorbing portion of the heat pipe is approximately coplanar with another surface of the plate component.

9. The circuit board structure as claimed in claim 7, wherein a surface of the heat absorbing portion and a surface of the heat dissipating portion of the heat pipe are approximately coplanar with one of the surfaces of the plate component.

10. The circuit board structure as claimed in claim 7, wherein the plate component is a laminated plate, the accommodating slot is formed between the two surfaces of the plate component, and the heat conductive component is embedded in the plate component.
